(19) United States
(12) Patent Application Publication
(10) Pub. No.: US 2006/0193019 A1
(43) Pub. Date: Aug. 31, 2006

(54) Image forming apparatus

(76) Inventor: Issei Nakano, Osaka (JP)

Correspondence Address: JORDAN AND HAMBURG LLP, 122 EAST 42ND STREET, SUITE 4000, NEW YORK, NY, 10168, US

(21) Appl. No.: 11/363,977

(22) Filed: Feb. 27, 2006

(30) Foreign Application Priority Data
Feb. 28, 2005 (JP) 2005-053392

(51) Int. Cl. G03F 3/08

(52) U.S. Cl. 358/521

(57) ABSTRACT

The object of this invention is to provide an image forming apparatus which is capable of obtaining an appropriate toner density with respect also to low exposure amount value (low gradation value) of the formed image, by using the conversion rule sufficiently approximating the characteristic between an exposure amount and an output time as a conversion rule for converting indicating values such as exposure amount value and gradation value into the output time (performing output control of the beam light to a light source). In this invention, the conversion rule is nonlinear so as to sufficiently approximate the characteristic between the exposure amount and the output time.

### BACKGROUND OF THE INVENTION

1. Field of the Invention

The present invention relates to an image forming apparatus, and particularly relates to an image forming apparatus suitable for forming an image using low-level density gradation (exposure amount).

2. Description of the Related Art

In image forming apparatuses being able to apply this invention such as printers, facsimiles and copy machines, various processing is performed to the inputted image information, and indicating values, such as the gradation value indicating the density level of the developer (hereinafter referred to as “toner”) attached to the photoreceptor drum per pixel, and the exposure amount value indicating the light amount (hereinafter referred to as “exposure amount”) of the beam light for exposure in proportion of said gradation value, are allotted (per pixel). Thus, the image data should be formed as an image is generated.

In addition, emission control of the light source that outputs the beam light for writing an electrostatic latent image onto the photoreceptor drum is conducted in the aim of forming an electrostatic latent image (an image of electric potential) equivalent to the generated image data (in other words, realizing the distribution of the above-mentioned density level) onto the photoreceptor drum. In other words, for example, as disclosed in Japanese Patent Publications No. S63-49779 and No. 2004-258482, the emission control time (later-descried output time) of the light source corresponding to the gradation value allotted per pixel is determined, and based on such time, the output control (exposure amount control) of the beam light of the light source is conducted, thereby forming an electrostatic latent image onto the photoreceptor drum.

FIG. 1 illustrates a general block diagram of a copy machine according to a conventional example. Hereinafter, as referring to FIG. 1, a copy machine according to the conventional example is described.

The construction of a copy machine B shown in FIG. 1 is generally categorized into a document reader X1, a paper feeder X2, a printing member X3, and a paper ejector X4. Document reader X1 is positioned on the upper side of Paper feeder X2, and Printing member X3 is positioned in the center between Document reader X1 and Paper feeder X2.

Document reader X1 comprises a document setting member 1, an automatic document feeder (hereinafter referred to as “ADF”) 2, a document platform 3, a document ejector 4, a exposing apparatus 5, light guiding mirrors 6a, 6b and 6c, an optical lens 7, CCD 8 and a controller 9.

ADF 2 sequentially delivers a document S set in Document setting member 1 one by one through a plurality of delivering rollers in accordance with the printing requirement sent from a operation panel (not shown) which is positioned on such as the front surface of Copy machine B. Document S delivered by ADF 2 is then delivered in the sub-scanning direction through the prescribed reading position on Document platform 3 consisted of such as platen glass, and then discharged into Document ejector 4.

In addition, light is emitted by Exposing apparatus 5 onto Document S moving on a prescribed reading position of Document platform 3 in the sub-scanning direction (the direction from the left side to the right side in FIG. 1). The reflected light from the above Document S is light-guided by Light guiding mirrors 6a, 6b and 6c, and is condensed by Optical lens 7. Also, by means of CCD8, the image information included in the reflected light is converted into an electronic signal (hereinafter referred to as “image information signal”), thereby being read into Controller 9.

Controller 9 is provided with peripheral devices such as MPU, ROM and RAM, and by executing the control program previously memorized in such ROM, conducts the overall control of Copy machine B, including such as image processing of the image information.

Controller 9 performs various processing with respect to the image information signal, and thus, as described above, allots the exposure amount value (one example of the indicating values) based on the gradation value indicating toner density in each pixel, thereby generating an image data of the image that should be formed. Additionally, the exposure amount value to each pixel is converted into output time of emission order signal being output to a light source 15 in accordance with the later-described conversion rule memorized in ROM that is included in Controller 9.

In addition, the gradation value directly indicates the toner density that should be attached to per pixel, and is generally determined based on the image processing of the image information of the read document. Also, the exposure amount value literally indicates the light amount (exposure amount) that should be emitted to each pixel.

As described later, the density of toner to be attached to each pixel depends on the electric potential of the pixel. Also, the electric potential varies according to the exposure amount emitted to the pixel. Consequently, the exposure amount value and the gradation value have a known corresponding relationship, and can be regarded as equivalent to each other except for various noises. In the present application, such as the gradation value and the exposure amount value as the indicator of the toner density are referred as “indicating values”.

Paper feeder X2 is schematically consisted of such as a paper cassette 10, a paper feed roller 11, and a remaining paper counter 12. In Paper cassette 10, a printing paper S′ is previously placed. With the above-mentioned printing requirement, Paper feed roller 11 is rotationally driven by Controller 9, and delivers Printing paper S′ placed in Paper cassette 10 to Printing member X3. The remaining amount of Printing paper S′ placed in Paper cassette 10 is detected by Remaining paper counter 12, and when the remaining amount is low, a prescribed indication for prompting paper refilling to the user is executed from the display panel provided in the exterior of the present Copy machine B.

Printing member X3 is schematically consisted of such as a delivery roller 13, a photoreceptor drum 14, a light source 15, a lens 16, a polygon mirror 17, a charging unit 18, a developing apparatus 19 and a fixing apparatus 20.

Printing paper S′ is delivered by means of Delivery roller 13. Photoreceptor drum 14 is uniformly charged in its surface by means of Charging unit 18.

Light source 15 emits light only while the emission order signal is being inputted from Controller 9, and exposes Photoreceptor drum 14 (one example of image supporters) by outputting the beam light for writing an electrostatic latent image. The emission order signal is inputted by Controller 9 into Light source 15 according to the output time converted as described above. The beam light output according to the input value of the emission order signal is emitted to Photoreceptor drum 14 through the optical instruments such as Lens 16 and Polygon mirror 17.

In addition, in each pixel on Photoreceptor drum 14, the electric potential according to the light amount of the emitted beam light is generated. In particular, electrification by Charging unit 18 is cancelled according to the exposure amount (the amount obtained from the time integration of intensity of the beam light, and having energy dimension) of the emitted beam light, thereby changing the electric potential. As described above, in each pixel on Photoreceptor drum 14, an image of the electric potential according to the toner density that should be attached, in other words, an electrostatic latent image is formed.

The toner on a developing roller provided to Developing apparatus 19 is pulled onto the surface of Photoreceptor drum 14, and with such toner, the electrostatic latent image is developed as a toner image in accordance with the electric potential gap (developing bias) between Photoreceptor drum 14 and the developing roller. Adjustment of the developing bias is conducted by adjusting the attaching electric potential by Controller 9 with respect to the developing roller provided to Developing apparatus 19 and placed opposite to Photoreceptor drum 14.

The toner image formed on Photoreceptor drum 14 is transferred onto Printing paper S′ delivered by Delivery roller 13. Then, Printing paper S′ on which the toner image is transferred is delivered to Fixing apparatus 20, and the toner image is fixed on Printing paper S′ by such as a heat roller. Printing paper S′ on which the toner image is fixed is now delivered to Paper ejector X4, and then ejected.

In addition, the conversion rule memorized in the ROM for converting the exposure amount value (indicating value) allotted in each pixel in the image data into the output time of emission order signal has a linear shape as shown in FIG. 2.

The reason for employing such conversion rule is as follows. In short, the exposure amount is the time integration of the beam light intensity from the light source, and is proportional to the input time (referred to the output time) of the emission order signal when the intensity of the beam light is under a certain condition. Consequently, the linear conversion rule is expected to approximate the characteristic between the exposure amount and the output time with high accuracy.

Also, the electric potential directly connected to the toner density is formed according to the exposure amount as described above, and such relationship has a linear shape (so called, E-V characteristic) until saturates as shown in FIG. 3. Therefore, by changing the output time into a linear shape according to the exposure amount value (indicating value) as shown in FIG. 2, and by inputting the emission order signal according to the output time into Light source 15, a proper electric potential with respect to the exposure amount value is expected to be generated on Photoreceptor drum 14.

However, the surface of Photoreceptor drum 14 is not always charged uniformly (in other words, has unevenness in electrification amount), and further, there is unevenness also in the cancel amount (displacement range of the electric potential) of the electrification amount in each exposure amount unit (energy). Furthermore, when the beam light is being uniformly output, as shown in FIG. 4, the emission intensity (exposure intensity) of the beam light varies according to the position of Photoreceptor drum 14 in the main scanning direction (in other words, a difference between peripheral light amount ratios occurs. for example, for the β point near the end in the main scanning direction, the emission intensity lowers compared to the α point near the center, and so as the cancel amount of the electrification)

According to these uneven electrification amount, uneven sensitivity and the difference in peripheral light amount ratio, the generated electric potential in each of positions in Photoreceptor drum 14 differs from the desired (appropriate to the exposure amount value and the gradation value) electric potential. In other words, even with a same exposure amount, there occurs unevenness in the generated electric potentials in each of pixels, and the density of toner to be attached varies.

As a technique for amending such unevenness in electric potentials, the techniques disclosed in, for examples, Japanese Patent Publication Nos. S63-49779 and 2004-258482 are well-known.

Japanese Patent Publication No. S63-49779 discloses an art in which distribution of uneven sensitivity on the surface of a photoreceptor drum is previously memorized for the purpose of amending the above-mentioned uneven sensitivity, and based on such memory, the output time of emission order signal to each pixel is amended.

Also, Japanese Patent Publication No. 2004-258482 discloses an art in which, as using a sensor for measuring distribution of electric potential on the surface of a photoreceptor, the output time or the electric current to the light source is adjusted according to the detected result of the sensor.

In particular, these arts disclosed in Japanese Patent Publication Nos. S63-49779 and 2004-258482 shift the linear conversion rule (the graph in FIG. 2), that converts the exposure amount value into the output time, up and down per pixel according to uneven sensitivity and uneven electrification per pixel. This enables the output time to be amended according to the uneven sensitivity and the uneven electrification per pixel, thereby obtaining an appropriate exposure amount with respect to the desired toner density (gradation value).

However, from the reason other than uneven electrification amount, uneven sensitivity and the difference in peripheral light amount ratio, a case may occur when the desired electric potential corresponding to the exposure amount value allotted in each pixel on Photoreceptor drum 14 cannot be generated. Such reason is as follows.

Illustrated in FIG. 5, is a graph indicating the time change of the beam light intensity according to a general laser light source. As shown in FIG. 5, the beam light intensity does not become a constant rated intensity right after the start of input of the above-mentioned emission order signal into the light source, and rather involves a rising period (and a falling period after cutting off the emission order signal) for gradually increasing the intensity. Consequently, since the output time converted by using the linear conversion rule includes the rising period as well as the falling period in which a constant rated intensity cannot be obtained, the exposure amount does not equal to the product between the constant rated intensity and the output time (shortly, the exposure amount does not simply become proportional to the output time).

Illustrated in FIG. 6 are plots indicating the relationship between the actual exposure amount and the output time (the while triangles are the plots). As shown in FIG. 6, in only the first area in the side of high exposure amount (high gradation), the characteristic of between the exposure amount and the output time is nearly linear, and the linear conversion rule as shown in FIG. 2 approximates the said characteristic with high accuracy. On the other hand, when including the second area in the side of low exposure amount (low gradation), the characteristic of between the exposure amount and the output time is nonlinear, and the approximating accuracy of the linear conversion rule to said characteristic therefore deteriorates. In other words, in the output time obtained by the linear conversion rule, a desired exposure amount cannot be obtained in the area in the side of the low exposure amount (additionally, the second area is considered as the area in which the percentage of the rising period occupying in the output time becomes high. on the other hand, the first area in which a constant rated intensity is obtained in the most of output time is considered as the area in which the exposure amount can approximate the product of between the rated intensity and the output time with high accuracy).

Additionally, in the conventional image forming apparatuses, the low exposure amount value (low gradation) corresponding to the second area is not used for image formation, and thus has actually little influence on the formed image even if using the linear conversion rule as mentioned above.

However, in the image forming method referred to as “high resolution enhancement method”, which is getting more attention recently, such low exposure amount value (low gradation value) corresponding to the second area is often used.

Consequently, when the linear conversion rule is used in the above case, an exposure amount according to the desired gradation value cannot be obtained, and there occurs severe errors in toner density in the part of low exposure amount value (low gradation value) in the formed image, thereby deteriorating the image quality.

Consequently, this invention has been invented considering the foregoing conditions, and the purpose of this invention is to provide the image forming apparatus capable of obtaining an appropriate toner density also in the part of low exposure amount value (low gradation value) in the formed image, by using a conversion rule in which the characteristic of between the exposure amount and the output time is sufficiently considered.

### SUMMARY OF THE INVENTION

In order to achieve the foregoing purpose, this invention is constituted as an image forming apparatus in which a light source for emitting light during input of a prescribed emission order signal is employed, and further, a conversion rule for converting an indicating value (such as, exposure amount value and gradation value) that indicates an exposure amount per pixel into an output time of the emission order signal is previously determined as nonlinear so as to approximate a nonlinear characteristic between an exposure amount from the light source and the output time, thereby outputting the emission order signal to the light source according to the converted output time.

Thus, the output time in the area in the side of low exposure amount (low gradation) is also required to be appropriate, and, with the emission order signal output to the light source according to the output time, an electrostatic latent image of the electric potential realizing a desired toner density is formed on a photoreceptor drum (image supporter).

Here, it can be contemplated as one example when the indicating value is divided into a plurality of ranges, and a different linear conversion rule is allotted in each of such divisions. In such case, where a characteristic between a light amount and the output time is as the one illustrated in FIG. 5, the characteristic can be easily approximated by allotting a different linear conversion rule in each of the divisions. On the other hand, the characteristic can be approximated by a complicated function such as a high-dimensional function.

In addition, when the characteristic between exposure amount and the output time as shown in FIG. 5 can be obtained, a different linear conversion rule may be employed for both of the divisions: one for low indicating value corresponding to the case when the ratio of the period when a rated intensity cannot to be obtained is high among the output time; and one for high indicating value corresponding to the case when the ratio of said period is low and the exposure amount nearly equals to the product between the output time and the rated intensity of the light source, thereby sufficiently approximating the characteristic.

Additionally, in the area in the side of low exposure amount (low gradation), the output time significantly involves the rising period of the beam light, and therefore, only the exposure amount lower than the desired exposure amount can be obtained. Thus, it is preferred to bring an uniform increase in a plurality of the divisions, and also, to determine the growing increasing rate (coefficient) in the area in the side of high exposure amount according to the linear conversion rule.

Here, the effect of the present invention can be particularly remarkable when a function which, based on the image data having the resolution higher than the one for image formation, generates an image data indicating said image in a pseudo manner at said resolution for image formation by using the gradation value of medium density gradation (so called, high-resolution enhancement image processing function) is comprised, since the frequency for the low gradation value (low exposure amount value) to be allotted in each pixel as the gradation value of medium density gradation becomes high.

Also, when the electrification distribution characteristic (uneven electrification) of the photoreceptor drum, the exposure sensitivity distribution characteristic (uneven sensitivity) and the variation in exposure intensity per position on the photoreceptor drum caused from an optical characteristic occurs, the present invention may preferably include functions for, such as amending the indicating value by the nonlinear conversion rule before being converted into the output time, or amending the nonlinear conversion rule.

In the present invention, the conversion rule, which is determined as nonlinear so as to approximate the nonlinear characteristic between the exposure amount from the light source and the output time, is employed as a conversion rule for converting the indicating values (such as exposure amount value and gradation value) indicating the exposure amount per pixel into the output time of emission order signal. Consequently the indicating value in an optional area can be converted into the appropriate output time, and an electrostatic latent image of an electric potential realizing a desired toner density is formed on a photoreceptor drum (image supporter).

### BRIEF DESCRITPTION OF THE DRAWINGS

FIG. 1 is a schematic structural view showing a copy machine according to an embodiment of the present invention;

FIG. 2 is a graph showing a conversion rule for converting a indicating value into an output time of an emission order signal employed in copy machines of the prior arts;

FIG. 3 is a graph showing a relationship (E-V characteristic) between electric potential on a photoreceptor and exposure amounts;

FIG. 4 is a graph showing a corresponding relationship between positions in a main scanning direction of a photoreceptor drum and emission intensity of a beam light;

FIG. 5 is a graph showing a time change of a beam light intensity by a light source;

FIG. 6 is a graph showing a corresponding relationship between exposure amount and output time;

FIG. 7 is a schematic diagram explaining a generating method for an image data of high-resolution enhancement.

FIG. 8 is a graph showing a conversion rule for converting indicating value into output time of an emission order signal employed in a copy machine according to an embodiment of the present invention.

FIG. 9 is a graph explaining an example of amendment of a conversion rule.

### DETAILED DESCRIPTION OF THE PREFERRED EMBODIMENTS

With embodiments of the present invention described hereinafter with reference to the accompanying drawings, it is to be understood that the invention is not limited to those precise embodiments, and that various changes and modifications may be effected therein by one skilled in the art without departing from the scope or spirit of the invention as defined in the appended claims.

(1) Features of a Copy Machine According to an Embodiment of the Present Invention

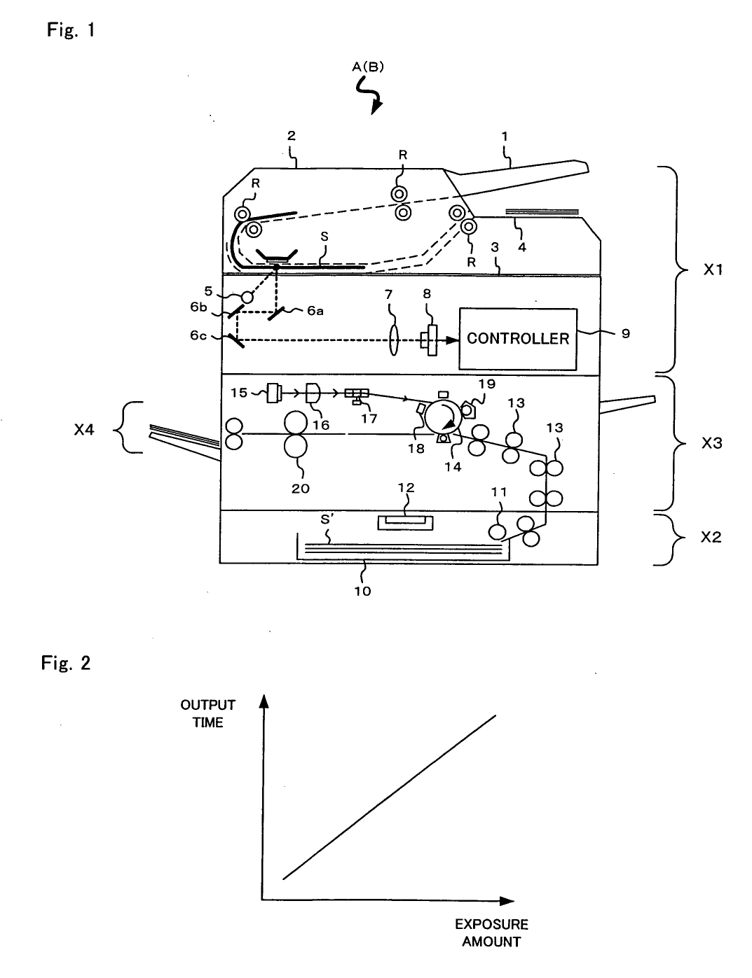

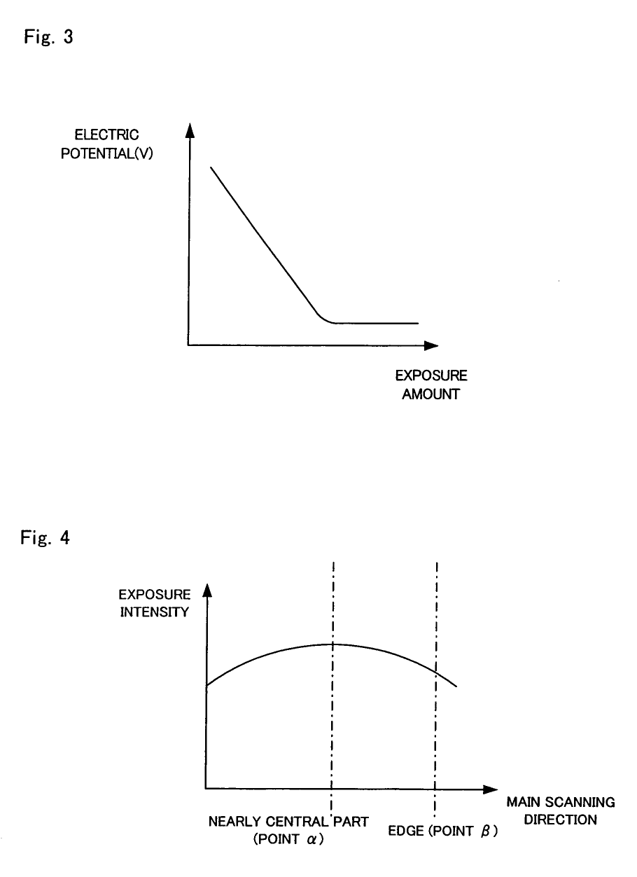

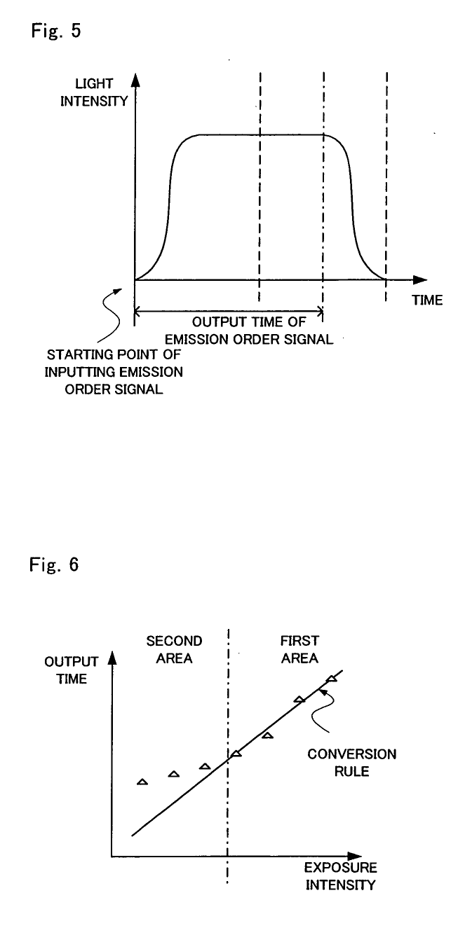

In FIG. 1, a schematic structural view of a copy machine A according to an embodiment of the present invention is illustrated. Copy machine A (one example of image forming apparatuses) has a different rule (conversion rule) for determining a output time of an emission order signal, that is output to a light source 15 shown in FIG. 1 and orders the beam light emission, from the one of a copy machine B according to a prior art.

In other words, similar to the prior art, image information of a copy target document is read by a document reader X1. With respect to such image information, various image processing are performed by a controller 9, and an image data in which gradation value (as mentioned above, nearly equivalent to the exposure amount, and one example of the indicating values) indicating a toner density that should be attached in each pixel are corresponded is generated. Additionally, for generating the image data, a high-resolution enhancement method is employed as described later in (2).

Also, in ROM in Controller 9, a conversion rule information for determining the nonlinear conversion rule described particularly in (3) is previously memorized. The gradation value in each pixel is converted into an output time of a prescribed emission order signal by the nonlinear conversion rule determined by the conversion rule information, and the emission order signal is output to Light source 15 for the period of such output time by Controller 9. Then, Light source 15 output the beam light for writing an electrostatic latent image only while the emission order signal are being input from Controller 9, and thus, Photoreceptor drum 14 is exposed, and an electrostatic latent image is written. By controlling the output time, an electric potential after exposure, in order words the toner density, in each of the pixels is controlled.

In addition, Copy machine A has a same structure as one of Copy machine B in regard to each part except for the processing information of Controller 9, and the explanation about such structure is omitted.

(2) High Resolution Enhancement Method

According to the present Copy machine A, high-resolution enhancement method is employed for obtaining the image data from the image information of the read document. Hereinafter, high-resolution enhancement method is described.

For example, the image data of the formed image is assumed at the resolution of 600 dpi. On the other hand, the image information of the document to be read is assumed at the resolution of 1200 dpi, being twice as much as said image data (higher than the resolution of the image data). In this case, the image data (hereinafter referred to as “image data of high-resolution enhancement”) that indicates the image of the resolution of 1200 dpi by the resolution of 600 dpi in a pseudo manner, is generated by Controller 9 (one example of the means for high-resolution enhancement image processing).

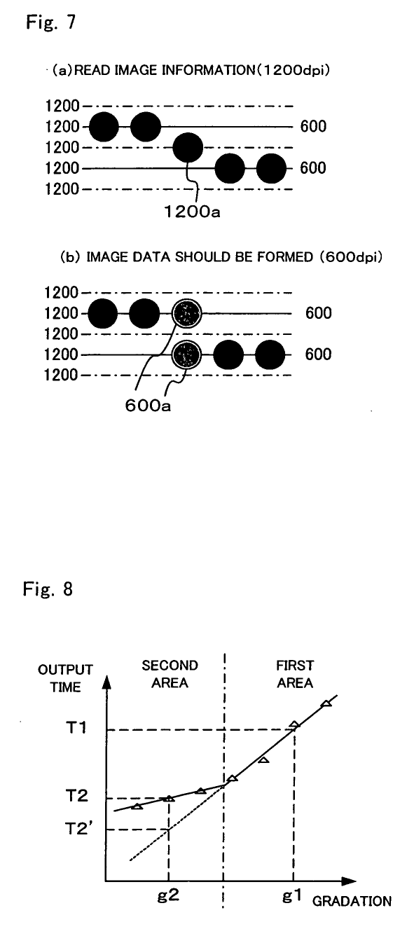

FIG. 7 is a schematic diagram explaining a generating method for an image data of high-resolution enhancement. Hereinafter as referring to FIG. 7, the generating method for an image data of high-resolution enhancement is explained.

As shown in FIG. 7 (a), in the read image information, the gradation values are allotted at each of the positions having a prescribed interval on pixel of 1200 dpi. On the other hand, when forming an image, the image information (of 1200 dpi) indicated in FIG. 7 (a) is converted into the image data (of 600 dpi) indicated in FIG. 7(b).

In particular, the gradation values (for example, 1200a shown in FIG. 7 (a)) allotted on the pixel lines, which do not exist in the case of 600 dpi image, among the gradation value allotted on the pixel lines in 1200 dpi are allotted on the pixel lines in the 600 dpi as each of two gradations (for example, two 600a shown in FIG. 7 (b)) lying side-by-side on the pixel lines of 1200 dpi. In addition, such gradation value after being allotted in the above manner is such as the gradation value of half of the original (1200 dpi) gradation value, and also is the gradation value of medium density including low gradation value.

As mentioned above, in an image data to be generated by Copy machine A according to one embodiment of this invention, gradation value of medium density (including low gradation value) is often used.

(3) Nonlinear Conversion Rule

In the image data generated by the high-resolution enhancement method as mentioned above, the gradation value to be allotted in each pixel is converted by the nonlinear conversion rule as a feature of Copy machine A into the output time for outputting the emission order signal to Light source 15. Hereinafter, the nonlinear conversion rule employed in Copy machine A is described.

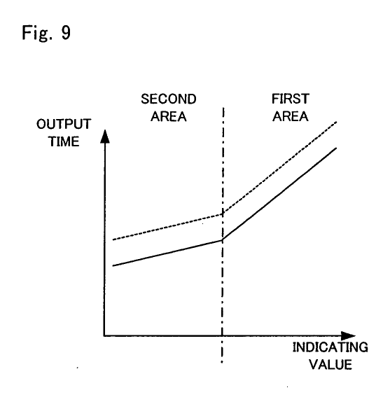

FIG. 8 is a graph showing a conversion rule for converting the gradation value (one example of indicating value) into output time of the emission order signal employed in a copy machine according to the embodiment of the present invention.

Additionally, similar to FIG. 6, a nonlinear characteristic between the exposure amount and the output time for obtaining the toner density corresponding to the gradation value is plotted as a white triangle in FIG. 8, and said conversion rule and the conversion rule shown in the second area according to the conventional example are respectively indicated in a full line and a dashed line. Controller 9 (one example of nonlinear conversion rules) converts the gradation value (one example of indicating value) into the output time by using the nonlinear conversion rule (a full line) indicated in FIG. 8.

In particular, the entire range of the gradation value (indicating value) is divided into two (one example of plurality) divisions (the first area and the second area in FIG. 8). Also, a different linear conversion rule is allotted to each of two divisions. These two divisions are consisted of: the first area in the side of high gradation (high exposure amount) in which Light source 15 outputs the beam light at a certain rated intensity for the most part of output time and also exposure amount approximates with high accuracy in the product between the rated intensity and output time, and the second area in the side of low gradation (low exposure amount) in which the rising time of Light source 15 occupies large ratio of the output time and the exposure amount cannot approximate in the product between the rated intensity and the output time.

In addition, the nonlinear conversion rule shows uniform increase across the entire range of the gradation value (one example of indicating value), and moreover, the increase rate (coefficient) in the linear conversion rule allotted to each division is set to higher in the first area in the side of high exposure amount. With above-mentioned conversion rule, it is understandable from FIG. 8 that the nonlinear feature between the exposure amount and the output time for obtaining the toner density corresponding to the gradation value can be sufficiently approximated.

In addition, rule using complicated functions such as high-dimensional function and exponential function can be used as a nonlinear conversion rule, and this enables the nonlinear characteristic to be approximated.

According to the above-mentioned nonlinear conversion rule, Controller 9 converts the gradation value (one example of indicating values) into the output time. For example, as shown in FIG. 8, when (in the image data generated by means for high-resolution enhancement image processing) the gradation value (one example of indicating value) allotted in a pixel is assumed as g1 in the first area, the output time is defined as T1. Also, the gradation value is assumed as g2 in the second area, the output time is defined as T2 (defined as T2′ according to the conversion rule in the conventional example, however this does not enable to obtain the exposure amount corresponding to the gradation value).

As mentioned above, even a low gradation value belonging to the second area can be also converted into an appropriate output time that can obtain the exposure amount corresponding to such low gradation value.

(4) Exposure on a Photoreceptor Drum

Controller 9 outputs the emission order signal to Light source 15 in accordance with the output time per pixel obtained by the nonlinear conversion rule as mentioned above. Also, Light source 15 starts the rising of the beam light at the input starting point of the emission order signal, and emits the beam light toward Photoreceptor drum 14 as well as performs the output stop motion of the beam light at the input stop point of the emission order signal. This enables the generation of the electric potential, which corresponds to the gradation value allotted in the image data, in each pixel on Photoreceptor 14, thereby generating an electrostatic latent image.

As mentioned above, by setting the conversion rule for converting the gradation value allotted in each pixel in the image data into the output time of the emission order signal as nonlinear, the appropriate exposure amount can be obtained with respect also to the low gradation value obtained by high-resolution enhancement method, and furthermore, the deterioration of image quality in the part of low exposure amount value (low gradation value) in the formed image can be prevented.

In the above embodiment, a copy machine is cited as one example of image forming apparatuses, however, the present invention is not limited to this, and can be applied to facsimiles, printers and the complex machines having the combination of these functions.

Additionally, in the above embodiment, the image data for image formation can be obtained by high-resolution enhancement method, however, this invention can also be applied to the image forming apparatus which obtains image data by other methods. In other words, the high-resolution enhancement method is merely considered as one example of typical image processing in which low gradation value is often employed.

Moreover, in the above embodiment, the gradation value is allotted in each pixel as the image data for image formation, however this is not intended to limit the scope, and for example, such as the exposure amount value indicating the necessary exposure amount can be allotted too.

Also, as the copy machine according to the present invention described in the following, functions for amending the indicating values such as the gradation value and the exposure amount may be comprised.

In other words, as mentioned above, the surface characteristic on Photoreceptor drum 14 (one example of the image supporter, see FIG. 1) generates unevenness in the electrification distribution (uneven electrification), and also there occurs unevenness in the cancel amount of electrification (uneven sensitivity) per unit exposure amount (energy). Further, even when the beam light is output uniformly, as shown in FIG. 4, the emission intensity (exposure intensity) of the beam light changes (difference in the peripheral light amount ratio) according to the positions of the main scanning direction of Photoreceptor drum 14. According to these error causes such as uneven electrification, uneven sensitivity, and difference in the peripheral light amount ratio, the electric potential generated in each position on Photoreceptor drum 14 does not mark the desired (appropriate to the gradation value and the exposure amount value) electric potential.

Controller 9 (one example of the first means for amending threshold value and the second means for amending threshold value) has a function for amending the indicating value (gradation value and exposure amount value) allotted in each pixel in the image data for image formation according to a part or all of these error causes (uneven electrification, uneven sensitivity, and difference in the peripheral light amount ratio).

In other words, the information identifying the amending rule of the indicating value with respect to each pixel on Photoreceptor drum 14 is memorized in the ROM included in Controller 9. In particular, the information of error causes such as uneven electrification, uneven sensitivity, and difference in the peripheral light amount ratio on Photoreceptor drum 14 are previously identified by such as experiments, and identifying information of amending rule of the indicating value which is based on the above-mentioned information is determined in each pixel. For example, with respect to the pixel having the characteristic of low cancel amount of electrification per unit exposure amount, the attached toner density tend to become low, and therefore, the amending rule performing increasing amendment of the indicating value (gradation value and exposure amount value) is determined. Also, with respect to the pixel in the central direction in the main scanning direction where the emission intensity of the beam light is large, the attached toner density tends to become high, and thus determines the amending rule performing reduction amendment to the indicating value (gradation value and exposure amount value).

With the above-mentioned functions, the indicating value (gradation value and exposure amount value) previous to be converted in to the output time by the nonlinear conversion rule is amended according to the error causes (uneven electrification, uneven sensitivity, and difference in the peripheral light amount ratio), and thus enables the prevention of the deterioration of image quality caused from the error causes.

In addition, this invention also obtains the effect of the same sort by amending the nonlinear conversion rule as illustrated in FIG. 9 instead of amending the indicating value. For example, when amending the difference of the peripheral light amount ratio as illustrated FIG. 4, the nonlinear conversion role (graph indicated in a dashed line in FIG. 9) employed to the pixel at β point should be amended so as to obtain the longer output time than the one obtained by the nonlinear conversion role (graph indicated in a full line in FIG. 9) employed to the pixel at α point.

What is claimed is:

1. An image forming apparatus for writing an electrostatic latent image by exposing an image supporter with light of a light source which emits light according to a prescribed emission order signal, comprising;
a nonlinear conversion means for converting an indicating value indicating exposure amount in each pixel into output time of said emission order signal according to a nonlinear conversion rule approximating a nonlinear characteristic between exposure amount of said light source and output time of said emission order signal, and
an order output means for outputting said emission order signal to said light source according to said output time obtained by said nonlinear conversion means.

2. An image forming apparatus according to claim 1 wherein said nonlinear conversion means converts said indicating value into said output time of emission order signal according to a different linear conversion rule in each division multi-dividing a whole range of said indicating value.

3. An image forming apparatus according to claim 2 wherein said division is an each range divided into two: a low gradation side and a high gradation side, in a whole range of said indicating value.

4. An image forming apparatus according to claim 2 wherein said linear conversion rule indicates an uniform increase across a whole range of said indicating value, and additionally an increasing rate of said linear conversion rule grows high in a high exposure amount side in said division.

5. An image forming apparatus according to claim 3 wherein said linear conversion rule indicates an uniform increase across a whole range of said indicating value, and additionally an increasing rate of said linear conversion rule grows high in a high exposure amount side in said division.

6. An image forming apparatus according to claim 1 comprising a means for high-resolution enhancement image processing for generating an image data which indicates an image based on an image data of higher resolution than a resolution for image formation by using a pixel gradation value of medium density gradation in a pseudo manner at said resolution for image formation, wherein said indicating value is a pixel gradation value or a corresponding value thereof in an image data generated by said means for high-resolution enhancement image processing.

7. An image forming apparatus according to claim 1 further comprising a first amending means of indicating value for amending said indicating value according to electrification distribution and/or exposure sensitivity distribution of said image supporter.

8. An image forming apparatus according to claim 1 further comprising a second amending means of indicating value for amending said indicating value according to exposure intensity distribution in each position in said image supporter.
